(19) United States
(12) Patent Application Publication
(10) Pub. No.: US 2023/0317705 A1
(43) Pub. Date: Oct. 5, 2023

(54) THIN CLIENT FORM FACTOR ASSEMBLY

(71) Applicant: Intel Corporation, Santa Clara, CA (US)

(72) Inventors: Carlton Hanna, San Jose, CA (US); Bernd Waidhas, Pettendorf (DE); Georg Seidemann, Landshut (DE); Stephan Stoeckl, Schwandorf (DE); Pouya Talebbeydokhti, Gilbert, AZ (US); Stefan Reif, Muenchen (DE); Eduardo De Mesa, Munich (DE); Abdallah Bacha, Munich (DE); Mohan Prashanth Javare Gowda, Ottobrunn (DE); Lizabeth Keser, San Diego, CA (US)

(21) Appl. No.: 17/707,366

(22) Filed: Mar. 29, 2022

(51) Int. Cl. H01L 25/18; H01L 23/538; H01L 25/065; H01L 25/10; H01L 25/00; H05K 1/18

(52) U.S. Cl. CPC H01L 25/18; H01L 23/5384; H01L 25/0657; H01L 25/105; H01L 25/50; H05K 1/181; H01L 2225/06572; H01L 2225/06517; H01L 2225/06589; H01L 2225/1035; H01L 2225/1094; H05K 2201/09072; H05K 2201/10378; H05K 2201/10734

(57) ABSTRACT

An electronic system has a printed circuit board and a substrate. The substrate has two sides, a top and bottom. At least one memory unit is connected to the bottom side of the substrate and at least one processor is connected to the top side of the substrate. The memory is connected to the processor with interconnects that pass through the substrate.

### TECHNICAL FIELD

This document pertains generally, but not by way of limitation, to a thin client form factor assembly for use in computer or electronic systems.

### BACKGROUND

Computer chips, and other similar components for electronic systems are becoming smaller or more compact. The current size and shape of the components on a computer chip or an electronic system can be prohibitive to the final size of the desired device. The necessary components on a computer chip dictate the overall dimension and configuration.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an illustration of an example cross section of an electronic system with minimal height.

FIG. 2 is an illustration of an example cross section of an electronic system with minimal height.

FIG. 3 is an illustration of an example cross section of an electronic system with minimal height.

FIG. 4 is an illustration of an example cross section of an electronic system with minimal height.

FIG. 5 is an illustration of a process flow for forming an electronic system with minimal height.

FIG. 6. is an illustration of a system level diagram, depicting an example of an electronic system.

### DETAILED DESCRIPTION

A system-on-chip is a single platform that integrates an electronic system on a single chip; such as by placing a central processing unit (CPU), internal memory or ports on the same platform. A system-on-chip can increase the speed of data transmission including transmission of high bandwidth data. A system-on-chip configuration can also decrease the latency or interconnection delays.

System-on-chip technologies that are packaged can require multiple dies assembled in a large package with more highspeed memory to communicate within the logic or processor dies. When more high bandwidth data is exchanged across the dies, the memory and the systems can slow down. Therefore, more memory is needed to increase the exchange rate of the high bandwidth of data. However, adding more memory increases the system or package footprint and can increase the height (in the Z dimension) of the overall assembly.

Adding memory to a system can be accomplished in several different exemplary manners. One example of adding memory is by connecting the memory through a processor that is not within the package. Memory can also be placed adjacent to the processor on a package substrate. This memory can be connected to the processor through a ball-grid array (BGA) and substrate routing. In another example, a flip chip ball grid array (fcBGA) is used. Alternate packaging options are also a way to connect additional memory to the system. For example, a 2.5D packaging is used with a silicon interposer or, in a 3D solution, a high bandwidth memory stack can be used and connected with the processor by an interposer.

When additional memory is added, components in a package or electronic system (hereinafter “system”) may need to be rearranged or modified to account for the overall form factor of the electronic system. The components in such an example system are either active components or passive components. Active components provide power gains to the systems. Active components include, for example, amplifiers, transistors, diodes, etc. Passive components do not generate power. Passive components dissipate, store or release power from the system. Passive components include, for example, resistors, capacitors, inductors, etc.

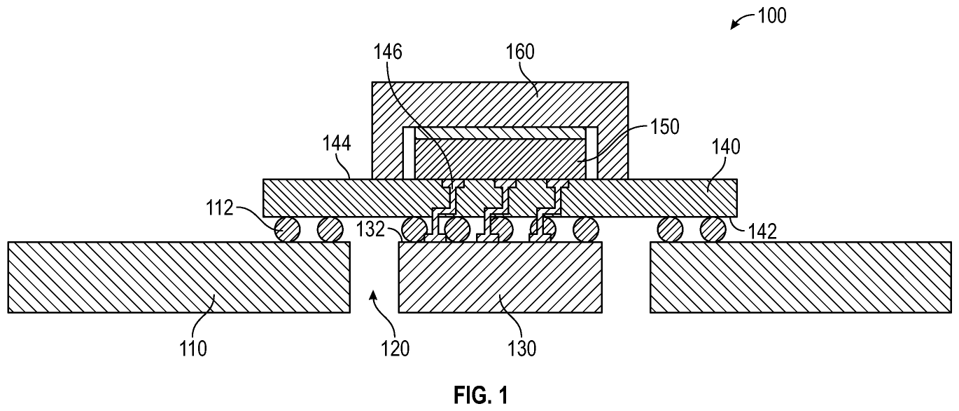

In an example of an electronic system 100, as illustrated in FIG. 1, a printed circuit board (PCB) 110 is provided with at least one recess, cavity, or cutout (“cavity”) 120. The cavity 120 is of a size and shape to accommodate at least one memory unit 130. The overall size of the cavity 120 is dictated by the intended use. The one memory unit 130 can be stacked memory, packaged memory or exposed silicon memory. The at least one memory unit 130 is embedded, placed, recessed within the cavity 120 with at least one side exposed (exposed side) 132. When the at least one memory unit 130 is embedded within the cavity 120, the height of the overall system 100 is reduced, as a memory unit can be an element which extends the overall height or Z dimension of the system.

The exposed side 132 is connected to a substrate 140 on a bottom side 142 of the substrate 140 with solder, such as balls, bumps or spheres 112. The solder balls 112 connect the at least one memory unit 130 with the substrate 140. The solder balls 112 can be in any arrangement, such as dual in-line, flat package or in a ball grid array.

The substrate 140 is the base or support layer for a central processing unit (CPU) or processor 150 (hereinafter CPU and processor are used interchangeably). The substrate 140 can be made from silicon or copper. In an example, the substrate 140 is a layer of copper wires encased in resin. The processor 150 is connected to a top side of the substrate 140. The substrate 140 connects the at least one memory unit 130 to the processor 150. The substrate 140 is any size or shape which supports the processor 150. The substrate 140 extends to cover the exposed side 132 and the cavity 120.

The cavity 120 allows for the at least one memory unit 130 to be on the same substrate 140 as the processor 150 while not adding height to the overall dimensions of the system 100. When the at least one memory unit 130 is on the same substrate 140 as the processor 150, the connection between the at least one memory unit 130 and the processor 150 is faster and allows for more capacity for more high bandwidth communications. In an example when the processor 150 is on one side of the substrate 140 and the at least one memory unit 130 is on the other side (or second side) interconnects 144 between the processor 150 and the at least one memory unit 130 are shorter. When the interconnects 144 are shorter there can be faster speed in the communication between the processor 150 and the at least one memory unit 130.

The processor 150 or the system 100 can be covered with a heat spreader 160. The heat spreader 160 transfers heat from the system 100 to a heat sink or a heat exchanger; thereby preventing overheating and potential damage to the system 100.

In an example where the at least one memory unit 130 is installed in a cavity 120 the at least one memory unit 130 can be separately tested before installed or embedded in the cavity 120. When systems are built, the components of the system 100 can be tested before being connected, coupled or attached together. Testing of the components before being connected, coupled or attached to the PCB allows for efficiency in the overall assembly of the system 100. Testing can include speed tests, diagnostic tests, fault testing, or any other test to guaranty each component is operable before the system is fully assembled. For example, before being installed on the PCB 110, the components are coupled, attached or connected to a translator to perform the appropriate tests. In another example, automated testing equipment can be used to test individual components of the system 100.

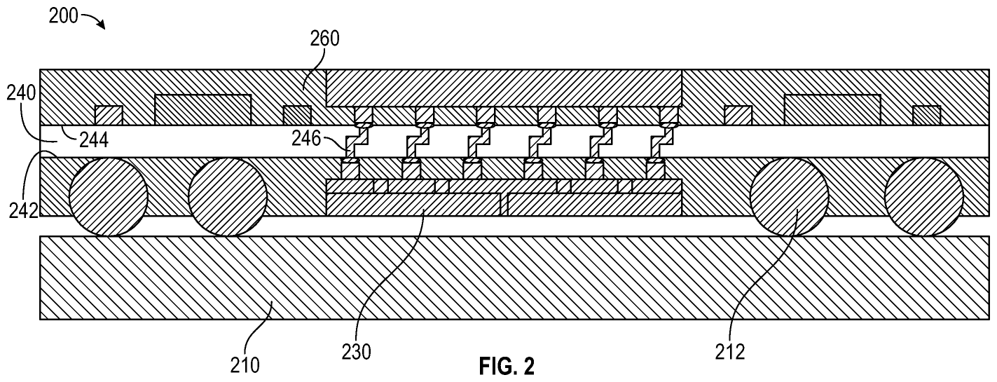

In another example of reducing the overall height of a system 200, as shown in FIG. 2, the at least one memory unit 230 is embedded within an encapsulant 260. In the example system 200 illustrated in FIG. 2, the at least one memory unit 230 is connected to a bottom side 242 of a substrate such as a redistribution layer 240 (or wafer level process). A redistribution layer 240 is an extra layer of wiring, such as copper wiring, that allows bonding from different locations on the system 200. The redistribution layer 240 can also spread contact points around the system 200 or die. In an example, the redistribution layer 240 can be used to decrease the height of the system 200. In the example illustrated in FIG. 2, the redistribution layer 240 is thinner than a substrate.

In the example illustrated in FIG. 2, the at least one memory unit 230 is directly installed as silicon memory. Silicon memory is thinner than packaged memory and therefore the overall dimension of the system 200 using the redistribution layer 240 and silicon memory 230 is a smaller package or system 200.

The at least one memory unit 230 connected, coupled or attached to the bottom side of the redistribution layer 240 is further connected to a processor 250 through the redistribution layer 240. The processor 250 is connected, coupled or attached to a top side 244 of the redistribution layer 240 with interconnects 246. In this example the processor 250 and the at least one memory unit 230 are connected to the same redistribution layer 240 or substrate.

As shown in FIG. 2, the substrate 260 is coupled or connected to a PCB 210 with solder, such as with solder balls 212. The solder balls 212 can be at least partially embedded in the encapsulant 260. In such an example, the embedded solder balls 212 are placed proximate to the at least one memory unit 230 and between the PCB 210 and the redistribution layer 240.

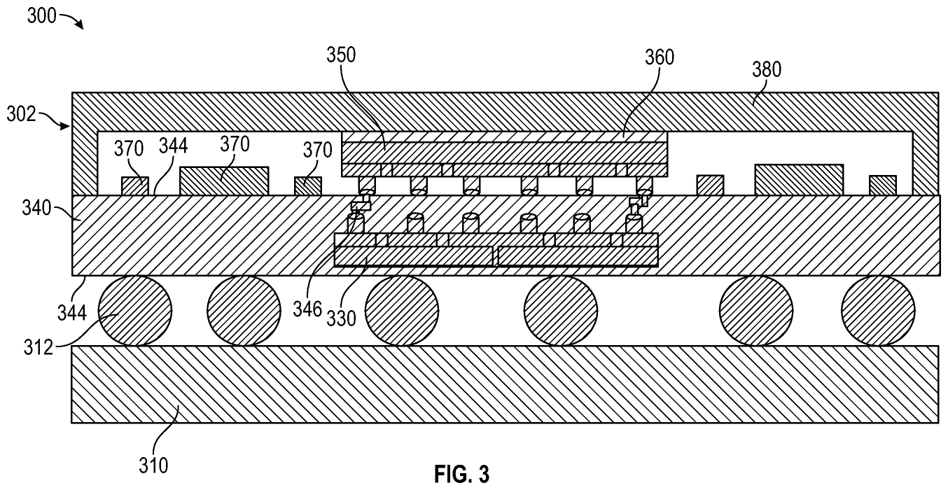

In the example system 300 shown in FIG. 3, at least one memory unit 330 is embedded or placed in the substrate 340. The substrate 340 (and each of the other substrates described herein) can be made of any suitable substance, such as a flexible material such as Polytetrafluoroethylene, Polyimide, PEEK; a semi-rigid material such as RO3000 and RO4000; or a rigid material such as a reinforced resin. The at least one memory unit 330 can be packaged memory, silicon memory or stacked memory, or any combination of memory suitable for the desired purpose. The at least one memory unit 330 embedded in the substrate 340 is embedded below the top side 344 of the substrate 340.

Interconnects 346 connect the at least one memory unit 330 with a processor 350 (CPU). The processor 350 is coupled or connected to the same substrate 340 as the at least one memory unit 330. Having the processor 350 and the at least one memory unit 330 on the same substrate 340 increases data transfer speed. Further, embedding the at least one memory unit 330 within the substrate 340 minimizes the overall dimension of the system 300 as the at least one memory unit 330 is not connected to a separate substrate or increasing the height of the system 300 by being placed on the same substrate. A heat spreader 360 can be connected, coupled or attached to the processor 350.

Passive components 370 such as resistors, transformers, or diodes, in the example of FIG. 3, can be placed at desired locations on the top side 344 of the substrate 340. The passive components 370 can, in this example, be directly connected to the processor 350.

The substrate 340 can be connected, coupled, attached to a PCB 310 by solder, such as with solder balls 312, bumps, spheres or any desired method of connecting the substrate to the PCB 310. In the example illustrated in FIG. 3, the solder balls 312 connect the PCB 310 to the bottom side 342 of the substrate 340.

Architecture 302 including the substrate 340 and embedded at least one memory unit 330, the processor 350, and the components 370 can be protected by packaging 380. The packaging 380 protects the components of the system 300 from environmental elements, damage and possible stresses. The type of packaging 380 used in the example illustrated in FIG. 3 (and in each of the examples shown or described herein) can be any packaging suitable for the desired use. For example, the packaging could be pin-grid array, lead-frame and dual-inline, chip scale, multiple chip or area array.

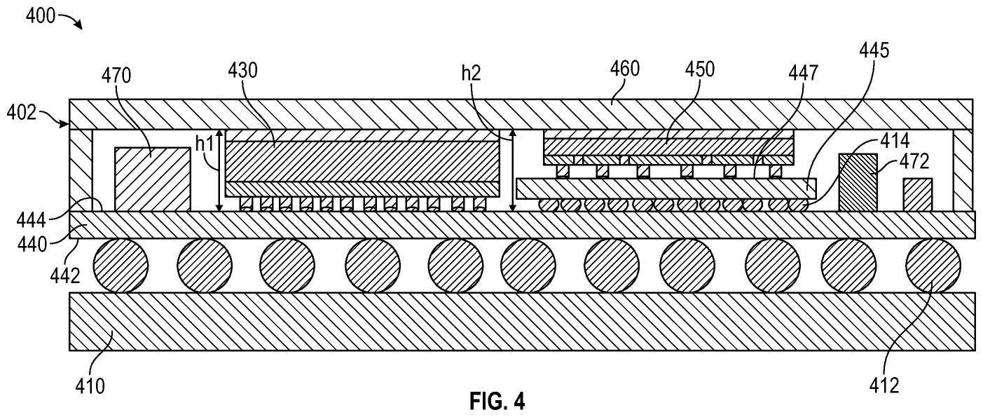

In the example system 400 illustrated in FIG. 4, there are at least two layers of substrate a thin substrate 440 and a thin interposer 445. The thin substrate 440 includes at least one layer of a substrate material. The thin substrate 440 is connected, coupled, attached to a PCB. The lower surface 442 of the thin substrate 440 is connected, coupled, attached to the PCB with solder, such as solder balls 412, bumps or spheres. The solder balls 412 can be disposed along the PCB 410 in an arrangement suitable for the desired purpose.

On the upper surface 444 of the substrate 440 at least one memory unit 430 is disposed. In the example illustrate in FIG. 4, the at least one memory unit 430 is packaged memory. The at least one packaged memory 430 in this example can be separately testable from other components in the system 400.

The thin interposer 445 is disposed on the thin substrate 440. The thin interposer 445 includes at least one layer of a thin interposer substrate. The thin interposer 445 is proximate or adjacent to at least one packaged memory 430 on the thin substrate 440. The thin interposer is connected, coupled or attached to the upper surface 444 of the thin substrate 440 with solder balls 414. A processor (CPU) 450 is connected, coupled or attached to a top surface 447 of the thin interposer 445. The processor 450 is connected to the same thin substrate 440 through the thin interposer 445. The thin interposer 445, in an example, has copper pillars or contacts for connections with components for the desired purpose.

The complexity needed below a processor 450 is higher than the complexity needed below the at least one packaged memory 430. For example, graphics may require more layers and, in such an example, the thin interposer 445 would have more layers than the thin substrate 440. In the example configuration illustrated FIG. 4, there can be multiple areas with different layers of thin interposer. In an example, the thin substrate 440 has at least as many layers as the thin interposer 445 and is therefore approximately the same thickness. In an example, the thin substrate 440 has a different number of layers of substrate material and is therefore a different thickness than the thin interposer 445. In an example, the thin substrate 440 is six layers of substrate material and the thin interposer 445 is six layers of interposer substrate. The material used for the layers of the substrate material and the interposer substrate can be the same material. In another example, the material used for the layers of the substrate material and the interposer substrate are different materials. The number of layers for the thin substrate 440 or the thin interposer 445 are any number which is dictated by the purpose of the at least one packaged memory 430 connected to the thin substrate 440. In an example, the at least one packaged memory 430 requires six layers for operation while the processor 450 requires twelve layers for operation. In this example, the stepped configuration of the system 400 illustrated in FIG. 4, provides the necessary number of substrate layers for the component attached to the specific area of an architecture 402. In this example the maximum height h1 of the memory 430, as measured from the thin substrate 440 is level with the maximum height h2 of the processor 450 as measured from the thin substrate 440.

The at least one packaged memory 430 is connected to the processor 450 through the thin substrate 440 and the thin interposer 445. With the packaged memory 430 disposed proximate to the processor 450 and on the same thin substrate 440, the speed of data transfer is increased. Surface-mount technology 470 or passive components 472 can be connected, coupled or attached to the upper surface 444 of the thin substrate 440. Surface-mount technology 470 or a surface-mount device can be an electrical component mounted directly on the surface of the PCB 410, such as resistors, capacitors, inductors, diodes. The surface-mount technology 470 or passive components 472 are connected, coupled or attached to the thin substrate 440 if the complexity of the thin substrate 440 supports the surface-mount technology 470 or passive components 472.

In the example illustrated in FIG. 4, a heat spreader 460 or thermal interface material is coupled to the architecture 402. The heat spreader 460, in this example can disseminate the heat from the packaged memory 430, the processor 450 or any other component on the thin substrate 440.

Each of the examples illustrated above can be encased in packaging to protect the system from environmental elements, damage or stresses. Such conditions can occur when the system is installed or used in a final device. The system could be a component of a computer system. They system could also be a component of a telecommunication system.

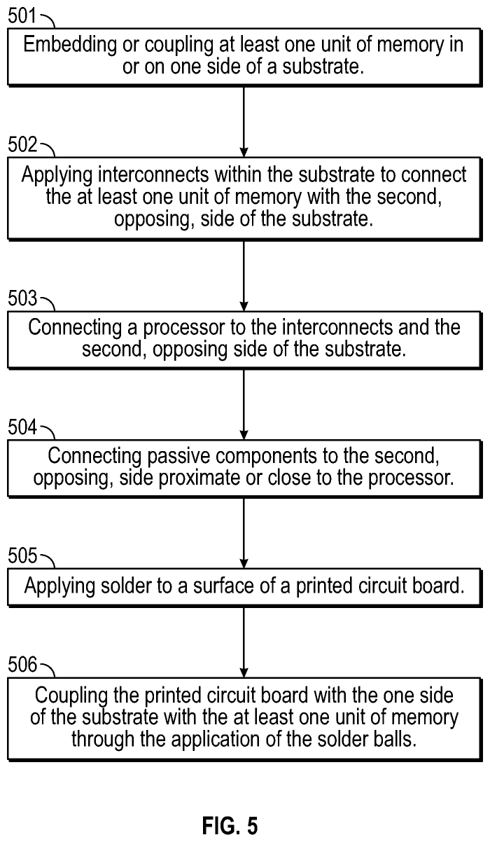

In an example illustrated by the flow chart in FIG. 5 at 501 at least one memory unit is embedded or coupled in a substrate on one side of a substrate. At least one memory unit could also be embedded on one side of the substrate. In an example, the at least one memory unit is embedded proximate to the one side of the substrate.

At 502 a plurality of interconnects are applied to or within the substrate. The interconnects connect the at least one unit of memory with the second and opposing side of the substrate. The interconnects, in an example, pass (extend) through the substrate and are exposed on the second and opposing side of the substrate. On one side of the substrate, the interconnects can be connected to the at least one memory unit.

At 503 a processor, or CPU, is connected to the interconnects. The processor is also connected to the second and opposing side of the substrate. The processor and the at least one unit of memory are on the same substrate but on opposing sides. Having the memory embedded in or on an opposing side of the substrate from the processor minimizes the height dimension of the system.

At 504 passive components are connected to the second and opposing side of the substrate. The passive components are proximate to or close to the processor. Active components and other features can also be assembled on or connected to the second and opposing side of the substrate.

At 505 solder, such as solder balls, are applied to a surface of a printed circuit board. The solder balls can be arranged in any arrangement as suitable for the desired purpose. The solder balls can also be applied to be embedded.

At 506 the substrate with the memory and processor connected, is coupled with the printed circuit board. The solder balls applied to the printed circuit board are used for coupling the substrate with the printed circuit board.

In this arrangement, the electronic system has minimal height. With the at least one memory unit embedded in the substrate the system is minimized because the memory is not accounted in the overall height and dimension of the system. Further, when the processor is connected last to the substrate, the memory can be separately tested for functionality. Any components which can be compromised before the system is completed can be replaced and thereby not damaging the system as a whole.

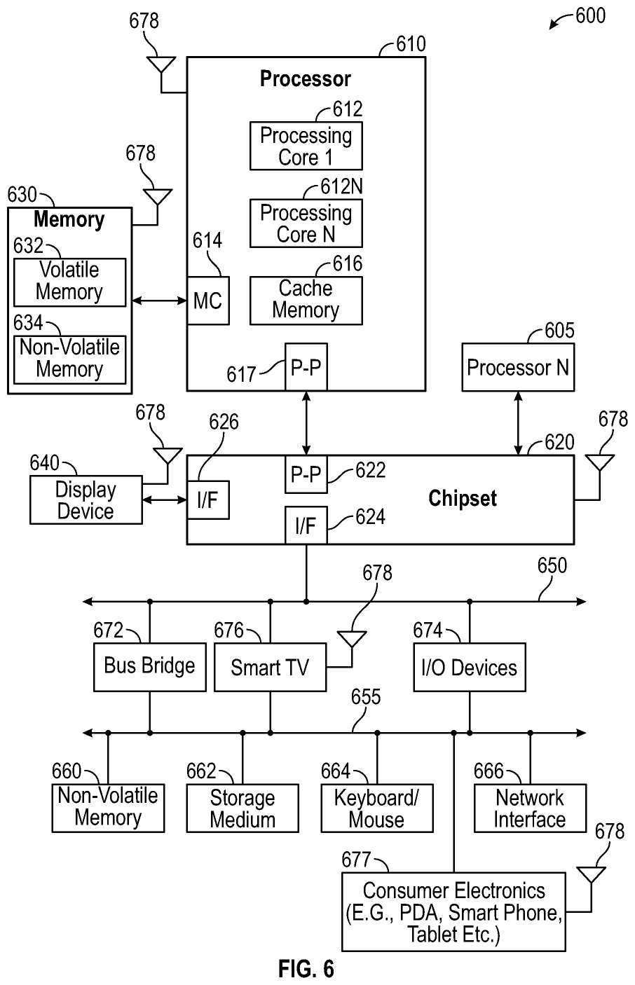

FIG. 6 illustrates a system level diagram, depicting an example of an electronic device (e.g., system) that may include an electronic system, for example, from any of the example process flows described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Various Notes and Aspects

Aspect 1 can include an electronic system with a printed circuit board, a substrate with a top and bottom side, at least one memory unit connected to the bottom side of the substrate and a processor connected to the top side of the substrate. The memory is connected to with the processor through the substrate

Aspect 2 can include, or can optionally be combined with the subject matter of Aspect 1, to optionally include the substrate is a redistribution layer.

Aspect 3 can include, or can optionally be combined with the subject matter of Aspect 1, to optionally include the printed circuit board is coupled with the substrate by solder.

Aspect 4 can include, or can optionally be combined with the subject matter of Aspect 1 or Aspect 3, to optionally include individual solder balls are partially embedded within the substrate.

Aspect 5 can include, or can optionally be combined with the subject matter of Aspect 1, to optionally include a cavity in the printed circuit board, the memory is within in the cavity and the memory is connected to the bottom side of the substrate with solder.

Aspect 6 can include, or can optionally be combined with the subject matter of Aspect 1, to optionally include a heat spreader disposed on the top side of the substrate and covering the processor.

Aspect 7 can include, or can optionally be combined with the subject matter of Aspect 1, to optionally include a memory that is packaged memory.

Aspect 8 can include an electronic system with a printed circuit board, a thin substrate with an upper and lower surface, where the printed circuit board is coupled to the lower surface of the thin substrate, at least one memory unit coupled to the upper surface of the thin substrate, at least one thin interposer with a top and bottom surface disposed on and coupled to the upper surface of the thin substrate and proximate to the at least one memory unit, and at least one CPU connected to the top surface of the thin interposer.

Aspect 9 can include, or can optionally be combined with the subject matter of Aspect 8, where the thin substrate includes as least as many layers of substrate material as a number of layers interposer substrate of the at least one thin interposer.

Aspect 10 can include, or can optionally be combined with the subject matter of Aspect 8, the thin substrate is at least six layers and the thin interposer is at least six layers.

Aspect 11 can include, or can optionally be combined with the subject matter of Aspect 8 where the printed circuit board is coupled to the lower surface of the thin substrate with soldering.

Aspect 12 can include, or can optionally be combined with the subject matter of Aspect 8 includes surface-mount technology coupled to the upper surface of the thin substrate.

Aspect 13 can include, or can optionally be combined with the subject matter of Aspect 8 above, where the at least one memory unit is packaged memory.

Aspect 14 can include, or can optionally be combined with the subject matter of Aspect 8, where the maximum height of the memory as measured from the thin substrate is level with the maximum height of the processor disposed on the thin interposer as measured from the thin substrate..

Aspect 15 can include, or can optionally be combined with the subject matter of Aspect 8, where a heat spreader is coupled to an architecture with a packaged memory and the CPU.

Aspect 16 can include, or can optionally be combined with the subject matter of Aspect 8, where the electronic system is a component of a computer system.

Aspect 17 can include, or can optionally be combined with the subject matter of Aspect 8, where the electronic system is a component of a telecommunication system.

Aspect 18 can include a method of making an electronic system with minimal height having at least the steps of forming an architecture. Where the architecture is formed by embedding at least one memory unit in a substrate, where the substrate has one side and a second, opposing side, applying a plurality of interconnect in the substrate, where the plurality of interconnects extend to the second, opposing side of the substrate, connecting the plurality of interconnects to the at least one memory unit in the substrate, connecting a processor to the second, opposing side of the substrate, and connecting the process to the interconnect. Coupling a printed circuit board with the architecture where the printed circuit board is coupled with the architecture on the one side of the substrate.

Aspect 19 can include, or can optionally be combined with the subject matter of Aspect 17, where the memory is embedded proximate to the one side of the substrate.

Aspect 20 can include, or can optionally be combined with the subject matter of Aspect 17, where the printed circuit board is coupled to the one side of the substrate with solder.

Aspect 21 can include, or can optionally be combined with the subject matter of Aspect 17, further comprising connecting passive components to the second, opposing side of the substrate.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. An electronic system comprising:
a printed circuit board;
a substrate having a top side and a bottom side, at least a portion of the bottom side coupled to the printed circuit board;
at least one memory unit connected to the bottom side of the substrate;
at least one processor connected to the top side of the substrate; and
wherein the memory is connected with the processor through the substrate.

2. The electronic system of claim 1 wherein the substrate is a redistribution layer.

3. The electronic system of claim 1 wherein the printed circuit board is coupled to the substrate with solder.

4. The electronic system of claim 3 wherein individual solder balls are partially embedded within the substrate.

5. The electronic system of claim 1 further comprising a cavity in the printed circuit board;
the at least one memory unit is within the cavity in the printed circuit board; and
the at least one memory unit is connected to the bottom side of the substrate with solder.

6. The electronic system of claim 1 wherein a heat spreader is disposed on the top side of the substrate and covering the processor.

7. The electronic system of claim 1 wherein the at least one memory unit is a packaged memory.

8. An electronic system comprising:
a printed circuit board;
a thin substrate including at least one layer of substrate material having an upper surface and a lower surface;
wherein the printed circuit board is coupled to the lower surface of the thin substrate
at least one memory unit coupled to the upper surface of the thin substrate;
at least one thin interposer including at least one layer of interposer substrate, having a top surface and a bottom surface, disposed on and coupled to the upper surface of the thin substrate and proximate to the at least one memory unit; and
at least one CPU connected to the top surface of the at least one thin interposer.

9. The electronic system of claim 8 wherein the thin substrate includes at least as many layers of substrate material as a number of layers interposer substrate of the at least one thin interposer.

10. The electronic system of claim 8 wherein the thin substrate is at least six layers and the thin interposer is at least six layers.

11. The electronic system of claim 8 wherein the printed circuit board is coupled to the lower surface of the thin substrate with solder.

12. The electronic system of claim 8 further comprising surface-mount technology coupled to the upper surface of the thin substrate.

13. The electronic system of claim 8 wherein the at least one memory unit is packaged memory.

14. The electronic system of claim 8 wherein a maximum height of the memory as measured from the thin substrate is level with a maximum height of the processor disposed on the thin interposer as measured from the thin substrate.

15. The electronic system of claim 8 wherein a heat spreader is coupled to an architecture including:
a packaged memory; and
the at least one CPU.

16. The electronic system of claim 8 wherein the electronic system is a component of a computer system.

17. The electronic system of claim 8 wherein the electronic system is a component of a telecommunication system.

18. A method of making an electronic system with minimal height comprising:
forming an architecture comprising:
embedding at least one memory unit in a substrate;
wherein the substrate has one side and a second, opposing side;
applying a plurality of interconnects in the substrate;
wherein the plurality of interconnects extend to the second, opposing side of the substrate;
connecting the plurality of interconnects to the at least one memory unit in the substrate;
connecting a processor to the second, opposing side of the substrate; and
connecting the processor to the interconnects; and
coupling a printed circuit board with the architecture;
wherein the printed circuit board is coupled with the architecture on the one side of the substrate.

19. The method of claim 18 wherein the at least one memory unit is embedded proximate to the one side of the substrate.

20. The method of claim 18 wherein the printed circuit board is coupled to the one side of the substrate with solder.

21. The method of claim 18 further comprising connecting passive components to the second, opposing side of the substrate.
